(19) United States
(12) Patent Application Publication
(10) Pub. No.: US 2026/0245843 A1
(43) Pub. Date: Aug. 20, 2026

(54) METHOD FOR PREDICTION OF ION ENERGY DISTRIBUTION IN PLASMA PROCESS

(71) Applicant: Tokyo Electron Limited, Tokyo (JP)

(72) Inventors: Gregory Hartmann, Austin, TX (US); Zhiying Chen, Austin, TX (US); Peter Lowell George Ventzek, Austin, TX (US); Shyam Sridhar, Austin, TX (US)

(21) Appl. No.: 19/214,855

(22) Filed: May 21, 2025

Related U.S. Application Data
(60) Provisional application No. 63/760,093, filed on Feb. 18, 2025.

(51) Int. Cl. H01J 37/32; G06N 3/08

(52) U.S. Cl. CPC H01J 37/32926; G06N 3/08; H01J 37/32972; H01J 2237/3323; H01J 2237/3343

(57) ABSTRACT

A method includes receiving a training data set, which includes one or more operating parameters of a plasma processing system and ion energy distribution function (IEDF) features corresponding to the one or more operating parameters. The one or more operating parameters include at least one process setpoint from a process recipe, at least one measured operating parameter, or at least one simulated operating parameter. The IEDF features include at least one measured IEDF feature or at least one simulated IEDF feature. The method further includes training an artificial neural network (ANN) using the one or more operating parameters as input, and the IEDF features as output. The ANN includes an input layer including one or more input nodes corresponding to the one or more operating parameters, a single hidden layer including one or more hidden nodes, and an output layer including output nodes corresponding to the IEDF features.

### CROSS-REFERENCE TO RELATED APPLICATIONS

This application claims the benefit of U.S. Provisional Application No. 63/760,093, filed on Feb. 18, 2025, which application is hereby incorporated herein by reference.

### TECHNICAL FIELD

The present disclosure relates generally to methods of processing a substrate, and, in particular embodiments, to methods for prediction of an ion energy distribution in a plasma process.

### BACKGROUND

Plasma processing systems are widely used in semiconductor manufacturing for various processes including etching and deposition. These systems typically include a plasma processing chamber where a substrate, such as a silicon wafer, is processed using plasma generated from various process gases. The plasma processing chamber may include components such as a substrate holder, a gas delivery system, vacuum pumps, electrodes, and various power sources for generating and sustaining the plasma.

In plasma processing, Radio Frequency (RF) power is commonly applied to generate and sustain the plasma. The RF power may be applied in continuous wave (CW) mode or in pulsed mode. Pulsed plasma processes involve the application of RF power in pulses, which can help generate high-energy ions while reducing charging effects. The RF power may be applied to both a source electrode for generating the plasma and a bias electrode for controlling the energy of ions striking the substrate.

### SUMMARY

In accordance with an embodiment, a method includes: receiving a training data set including: one or more operating parameters of a plasma processing system, where the one or more operating parameters include at least one process setpoint from a process recipe, at least one measured operating parameter, or at least one simulated operating parameter; and a plurality of ion energy distribution function (IEDF) features corresponding to the one or more operating parameters, where the plurality of IEDF features includes at least one measured IEDF feature or at least one simulated IEDF feature; and training an artificial neural network (ANN) using the one or more operating parameters as input, and the plurality of IEDF features as output, where the ANN includes: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes.

In accordance with another embodiment, a method includes: loading a pretrained artificial neural network (ANN) having as inputs one or more operating parameters of a plasma processing system, and as outputs a plurality of ion energy distribution function (IEDF) features corresponding to the one or more operating parameters of the plasma processing system, the pretrained ANN including: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes; receiving one or more runtime operating parameters of the plasma processing system; and predicting at least one IEDF feature utilizing the ANN with the one or more runtime operating parameters used as input.

In accordance with yet another embodiment, a controller includes: one or more processors configured to: receive a training data set including: one or more operating parameters of a plasma processing system, where the one or more operating parameters include at least one process setpoint from a process recipe, at least one measured operating parameter, or at least one simulated operating parameter; and a plurality of ion energy distribution function (IEDF) features corresponding to the one or more operating parameters, where the plurality of IEDF features includes at least one measured IEDF feature or at least one simulated IEDF feature; and train an artificial neural network (ANN) using the one or more operating parameters as input, and the plurality of IEDF features as output, where the ANN includes: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a schematic diagram of a plasma processing system, in accordance with some embodiments;

FIG. 2 illustrates graphs for one pulse period of a pulsed plasma process, in accordance with some embodiments;

FIG. 3 illustrates graphs of ion energy distributions functions (IEDF) in a pulsed plasma process, in accordance with some embodiments;

FIG. 4 illustrates a schematic diagram of an artificial neural network (ANN), in accordance with some embodiment;

FIG. 5 is a flow diagram of a method for training of an artificial neural network (ANN), in accordance with some embodiments;

FIG. 6 is a flow diagram of a method for utilizing a trained artificial neural network (ANN) for prediction of ion energy distribution function (IEDF) features, in accordance with some embodiments;

FIG. 7 illustrates a schematic diagram of an artificial neural network (ANN), in accordance with some embodiments;

FIG. 8A illustrates ion energy distribution function (IEDF) prediction results, in accordance with some embodiments;

FIG. 8B illustrates a graph of root mean square error (RMSE) during training of an artificial neural network (ANN), in accordance with some embodiments;

FIG. 9 illustrates ion energy distribution function (IEDF) features selected for prediction, in accordance with some embodiments;

FIG. 10 illustrates a schematic diagram of an artificial neural network (ANN), in accordance with some embodiments;

FIG. 11 illustrates a graph of root mean square error (RMSE) during training of an artificial neural network (ANN), in accordance with some embodiments;

FIG. 12 illustrates a mean ion energy predicted using an artificial neural network (ANN), in accordance with some embodiments;

FIG. 13 illustrates high and low peak intensities predicted using an artificial neural network (ANN), in accordance with some embodiments;

FIG. 14 illustrates a schematic diagram of a linear autoencoder artificial neural network (ANN), in accordance with some embodiments;

FIG. 15 illustrates a graph of mean absolute error (MAE) during training of a linear autoencoder artificial neural network (ANN), in accordance with some embodiments;

FIG. 16 illustrates a high peak center ion energy of the ion energy distribution function (IEDF) predicted using a linear autoencoder artificial neural network (ANN), in accordance with some embodiments;

FIG. 17 illustrates a high peak center ion energy of the ion energy distribution function (IEDF) predicted using a linear autoencoder artificial neural network (ANN), in accordance with some embodiments;

FIG. 18 illustrates a high peak intensity of the ion energy distribution function (IEDF) predicted using a linear autoencoder artificial neural network (ANN), in accordance with some embodiments;

FIG. 19 illustrates a peak maximum intensity of the ion energy distribution function (IEDF) predicted using a linear autoencoder artificial neural network (ANN), in accordance with some embodiments; and

FIG. 20 is a block diagram of a computing system, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While various embodiments of the present disclosure are described primarily in the context of plasma etching processes, it should also be appreciated that these embodiments may also apply to plasma deposition processes, plasma cleaning processes, and other plasma-based semiconductor manufacturing processes. In particular, various embodiments of the present disclosure may similarly apply to various types of plasma processing systems including capacitively coupled plasma (CCP), inductively coupled plasma (ICP), multi-frequency CCP, microwave plasma (MW), electron cyclotron resonance (ECR), and other suitable plasma generation systems.

In various embodiments, a method is provided for determining ion energy distribution functions (IEDF) and their features in plasma processing systems using artificial neural networks (ANNs). The method can utilize operating parameters of the plasma processing system to predict ion energy distribution function features without requiring direct measurement of the ion energy distribution during processing. This approach can be particularly advantageous for process development, monitoring, and control in production environments where direct measurement of ion energy distributions may be impractical.

In various embodiments, the method includes providing a training data set comprising operating parameters of a plasma processing system and corresponding ion energy distribution function features. The operating parameters may include process recipe setpoints such as source RF power, substrate RF bias power, pulse timing parameters, chamber pressure, and gas flow rates. The ion energy distribution function features may include measured or simulated data such as peak locations, peak intensities, mean ion energies, or the like. An ANN is then trained using these parameters as inputs and the ion energy distribution function features as outputs.

In various embodiments, the trained ANN can be used to predict ion energy distribution function features for runtime operating parameters during plasma processing. These predictions can be used to adjust process parameters to achieve desired process outcomes. For example, if a specific ion energy distribution is known to produce optimal etch profiles, the ANN can predict what operating parameters would yield that distribution, allowing for more precise process control.

In various embodiment, a simplified neural network architecture is used that can be effectively trained with sparse laboratory datasets. This approach can provide accurate predictions without requiring extensive historical process data. Additionally, the ANN can be implemented on simple hardware, making it suitable for integration with existing plasma processing systems. The method may also include principal component analysis to identify the operating parameters that most significantly influence the ion energy distribution, providing insights for process optimization.

In various embodiments, the trained ANN may be directly integrated with a controller of a plasma processing system. This integration allows for real-time prediction of IEDF features during processing without interrupting production. The controller can automatically adjust process parameters such as RF bias power, substrate bias potential, or pulse timing based on the predicted IEDF features to maintain desired process outcomes.

In various embodiments, a controller implementing an ANN may include a data collection module that continuously gathers operating parameters during processing. This collected data can be used for periodic retraining of the ANN to account for tool drift, chamber condition changes, or process modifications. This adaptive learning capability improves the long-term accuracy of the predictions and maintains process control even as equipment conditions evolve over time.

In various embodiments, a controller may implement multiple ANNs, with each ANN being configured for different process recipes or chamber configurations. This modular approach allows the controller to select the most appropriate ANN based on the current process requirements. For example, a separate ANN may be used for each gas chemistry, enabling more accurate predictions for specific process conditions without requiring a single complex ANN to handle all possible variations.

In various embodiments, an ANN employs strategic input parameter selection that significantly improves computational efficiency. Rather than using a complex network with numerous input parameters, the ANN is designed to operate with a minimal set of the most relevant input variables. This focused approach reduces the dimensionality of the input layer, decreasing both memory requirements and computational complexity during training and prediction modes while maintaining prediction accuracy.

In various embodiments, an ANN utilizes a streamlined architecture with a single hidden layer containing an optimized number of neurons. The design reduces the total parameter count compared to ANNs with multiple hidden layers. For example, an ANN with one input, 30 neurons in a single hidden layer, and 49 outputs requires only (1×30+30)+(30×49+49)=1579 weights plus biases, compared to tens or hundreds of thousands of parameters in typical deep learning models. This reduction in parameters allows for lower memory usage and faster inference times.

In various embodiments, an ANN utilizes an autoencoder design with a bottleneck layer containing a single neuron with a rectified linear unit activation function. This compact architecture allows the ANN to distill multiple input parameters into their essential components through a single neuron bottleneck. The resulting allows for reduced memory storage for weights and biases while still capturing the fundamental relationships between inputs and outputs. Additionally, the ANN provides dimensionality reduction capabilities, as the weights of the bottleneck neuron directly indicate the relative importance of each input parameter.

By integrating various embodiments described above, an ANN may achieve substantial improvements in functional efficiency, memory usage, and CPU requirements. The resulting architecture delivers accurate predictions with reduced computational resources, making it suitable for deployment on resource-constrained platforms while maintaining excellent performance characteristics.

FIG. 1 illustrates a schematic diagram of a plasma processing system 10, in accordance with some embodiments. The plasma processing system 10 comprises a plasma processing chamber 110 with excitation power source and substrate bias power source (in other words, wafer biasing capabilities). A substrate 100 may be placed on a substrate holder 105 within the plasma processing chamber 110. In various embodiments, the substrate 100 may be a part of, or including, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

In various embodiments, the plasma processing system 10 may further comprise a focus ring 154 positioned over the bottom electrode 120 to surround the substrate 100. The focus ring 154 may maintain and extend the uniformity of a plasma 160 to achieve process consistency at the edge of the substrate 100. In various embodiments, the focus ring 154 may have a width of a few cm. In various embodiments, there may be a gap for mechanical clearance between the circumference of the substrate 100 and the focus ring 154. In certain embodiments, the gap may be hundreds of microns to a few mm. In various embodiments, the focus ring 154 may comprise a dielectric material with a desired dielectric constant. In certain embodiments, the focus ring 154 may comprise silicon. Some examples of silicon-based focus ring may comprise silicon, silicon oxide, doped silicon (e.g., boron-doped, nitrogen-doped, and phosphorous-doped), silicon carbide, combinations thereof, or the like. Alternatively, in some embodiments, the focus ring 154 may comprise a carbon-based material. In one or more embodiments, the focus ring 154 may comprise a metal oxide, such as aluminum oxide, zirconium oxide, a combination thereof, or the like.

A process gas may be introduced into the plasma processing chamber 110 by a gas delivery system 115. The gas delivery system 115 may comprise multiple gas flow controllers to control the flow of multiple gases into the plasma processing chamber 110. Any precursors that can create a plasma may be used, such as argon (Ar), tetrafluoromethane (CF₄), oxygen (O₂), an admixture of tetrafluoromethane and oxygen (CF₄/O₂), hexafluorobutadiene (C₄F₆), octafluorocyclobutane (C₄F₈), nitrogen (N₂), hydrogen (H₂), hydrogen bromide (HBr), the like, or any combination, or admixture thereof in any suitable ratio. In some embodiments, optional center/edge splitters may be used to independently adjust the gas flow rates at the center and edge of the substrate 100. In various embodiments, a plasma process may be performed at the total flow rate of the process gas is in a range of 1 standard cubic centimeter per minute (sccm) to 5000 sccm, at a pressure in a range of 0.1 mTorr to 1 Torr, and/or at a temperature in a range of −200° C. to 500° C.

Further, in one embodiment, the gas delivery system 115 may have a special showerhead configuration positioned at the top of the plasma processing chamber 110. For example, the gas delivery system 115 may have a showerhead configuration, covering the entirety of the substrate 100, including a plurality of appropriately spaced gas inlets. Alternatively, the process gas may be introduced through dedicated gas inlets of any other suitable configuration. The plasma processing chamber 110 may further be equipped with one or more sensors such as pressure monitors, gas flow monitors, and/or gas species density monitors. The sensors may be integrated as a part of the gas delivery system 115 in various embodiments.

In FIG. 1, the plasma processing chamber 110 is a vacuum chamber and may be evacuated using one or more vacuum pumps 135, such as a single stage pumping system or a multistage pumping system (e.g., a mechanical roughing pump combined with one or more turbomolecular pumps). In order to promote even gas flow during plasma processing, gas may be removed from more than one gas outlet or location in the plasma processing chamber 110 (e.g., on opposite sides of the substrate 100).

In various embodiments, the substrate holder 105 may be integrated with, or a part of, a chuck (e.g., a circular electrostatic chuck (ESC)) positioned near the bottom of the plasma processing chamber 110, and connected to a bottom electrode 120. The surface of the chuck or the substrate holder 105 may be coated with a conductive material (e.g., a carbon-based or metal-nitride based coating). The substrate 100 may be optionally maintained at a desired temperature using a temperature sensor and a heating element connected to a temperature controller (not shown). In certain embodiments, the temperature sensor may comprise a thermocouple, a resistance temperature detector (RTD), a thermistor, a semiconductor based integrated circuit, or the like. The heating element may for example comprise a resistive heater in one embodiment. In addition, there may be a cooling element such as a liquid cooling system coupled to the temperature controller. The bottom electrode 120 may be coupled to a RF bias power source 130, such as through or controlled by a controller 170A.

In some embodiments, a voltage probe 172 is coupled to the substrate holder 105 or is otherwise present inside the plasma processing chamber 110. The voltage probe 172 may be used to measure a peak-to-peak voltage Vₚₚ of the plasma 160. This may be advantageous for adjusting the RF bias power frequency to achieve a stable peak energy of the ion energy distribution function (IEDF). The voltage probe 172 may be coupled to the controller 170A (or to another suitable controller or computer) to provide measurements of the peak-to-peak voltage Vₚₚ to the controller 170A.

Further in FIG. 1, a top electrode 150 may be a conductive helical coil electrode located outside the plasma processing chamber 110, positioned above a top plate 112. The top electrode 150 may be coupled to an RF power source 165 via a controller 170B. The top plate 112, a bottom plate 114, and a side wall 116 of the plasma processing chamber 110 may be conductive and electrically connected to a reference potential (e.g., system ground).

In some embodiments, the controller 170A and the controller 170B are coupled together or are part of a single controller, such as a programmable processor, microprocessor, computer, or the like. Although the controllers 170A and 170B are illustrated as two elements for illustrative purposes, the controllers 170A and 170B may include additional elements or be part of a single element. The controllers 170A and 170B may be programmable by instructions stored in software, firmware, hardware, or a combination thereof. The controllers 170A and 170B may be configured to set, monitor, and/or control various control parameters associated with generating a plasma and delivering ions to the surface of substrate 100. Control parameters may include, but are not limited to, power level, frequency, and duty cycle (%) for both the source power and the bias power as well as delay time (also referred to as lag time) between a source power pulse and a bias power pulse. Other control parameter sets may also be used.

In some embodiments, the operating pulse frequency range for the RF source power is 1 Hz to 1 MHz. While only one RF power source 165 is illustrated in FIG. 1, more than one RF power source(s) may be used in various embodiments, for example, to provide a low frequency RF power and a high frequency RF power at the same time. The plasma 160 may be generated and sustained by pulsed RF power.

In various embodiments, a RF pulsing at a kHz range may be used to power the plasma 160. Using the RF pulsing may help generate high energetic ions (>keV) in the plasma 160 for the plasma etch process, while reducing charging effects.

In some embodiments, the operating frequency range for the RF bias power is 100 kHz to 10 GHz. While only one RF bias power source 130 is illustrated in FIG. 1, more than one bias RF power source(s) may be used in various embodiments, for example, to provide a low frequency bias RF power and a high frequency bias RF power at the same time and enable changing the bias RF frequency more rapidly.

The configurations of the plasma processing system 10 described above is for example only. In alternative embodiments, various alternative configurations may be used for a plasma processing system that incorporates a set of electromagnets. For example, the plasma processing system may be a resonator such as a helical resonator that produces helicons. Further, microwave plasma (MW), electron cyclotron resonance (ECR), capacitively coupled plasma (CCP), multi-frequency CCP, inductively coupled plasma (ICP), or other suitable systems may be used. In various embodiments, the RF power, chamber pressure, substrate temperature, process gas flow rates and other plasma process parameters may be selected in accordance with the respective process recipe.

In some embodiments, the plasma processing system 10 may include one or more ion energy analyzers (not shown) configured to measure ion energy distribution functions (IEDF) and their features for purposes of process development, monitoring, and control, as described in U.S. Pat. No. 7,875,859, entitled “Ion Energy Analyzer and Methods of Manufacturing and Operating”, U.S. Pat. No. 7,777,179, entitled “Two-Grid Energy Analyzer and Methods of Manufacturing and Operating”, and U.S. Pat. No. 8,847,159, entitled “Ion Energy Analyzer and Methods of Manufacturing and Operating”, all of which are incorporated herein by reference in their entirety.

However, ion energy analyzers may be difficult to use for process monitoring in a production environment, as they need to be located either in place of the production substrate (e.g., substrate 100), or near it; their presence in the plasma processing chamber 110 may interfere with plasma process itself, or they may reduce the throughput of the plasma process, etc.

As described below in greater detail, IEDFs and their features may be determined without utilizing ion energy analyzers and instead by an artificial neural network (ANN) utilizing various parameters of the plasma process—both parameters set by the process recipe, parameters measured by sensors available on the plasma processing system, and/or parameters determined by plasma process simulations.

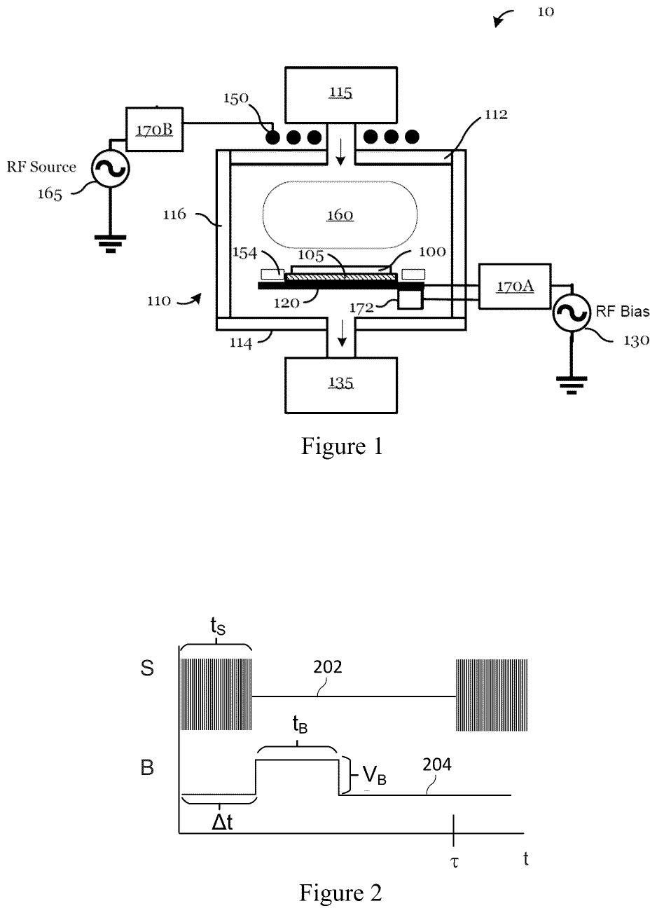

FIG. 2 illustrates timing diagrams for one pulse period of a pulsed plasma process, showing a temporal relationship between source power and bias power applications, in accordance with some embodiments. In particular, FIG. 2 depicts a waveform 202 (labeled “S” in FIG. 2) representing the source RF power application during the pulse period and a waveform 204 (labeled “B” in FIG. 2) representing the substrate bias power application during the same pulse period, plotted against time “t” on the horizontal axis. The total pulse period is denoted by τ, which encompasses both the source and bias pulses along with their relative timing.

The waveform 202 shows a rectangular AC pulse with a duration of t_{S}. The source power is applied at the beginning of the pulse period and remains active for the duration t_{S}. After the active period, the source power is turned off as shown by the horizontal line extending to the right. The waveform 204 shows a rectangular DC pulse with an amplitude of V_{B}. The bias power pulse has a duration of t_{B} and begins after a delay time Δt from the start of the source power pulse, creating a temporal offset between the two power applications.

In various embodiments, this pulsing configuration enables control over ion energy distribution in the plasma process. The temporal separation Δt between source power and bias power applications allows ions to be generated during the source power phase and then accelerated toward the substrate during the bias power phase. The duration of the bias pulse t_{B}, the magnitude of the bias voltage V_{B}, and the delay time Δt can be adjusted to modify the resulting IEDF and thereby control process outcomes such as etch rate, profile, and uniformity.

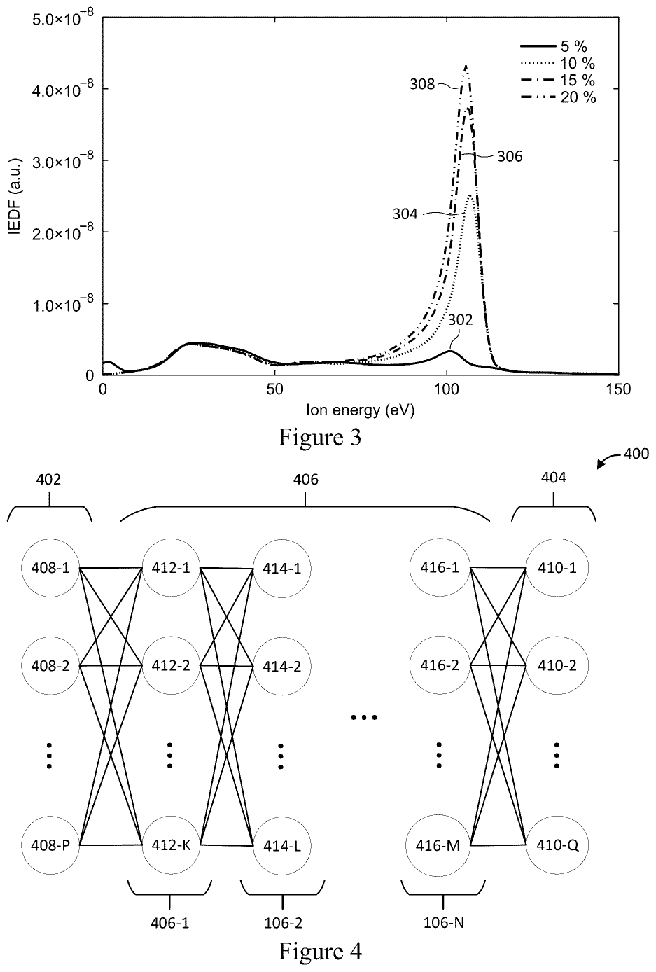

FIG. 3 illustrates graphs of IEDFs in a pulsed plasma process, in accordance with some embodiments. The IEDF graphs 302-308 are plotted with ion energy on the horizontal axis and ion intensity on the vertical axis, and demonstrate how the IEDF varies with different duty cycles of a pulsed plasma process. In particular, the IEDF graph 302 corresponds to a 5% duty cycle, the IEDF graph 304 corresponds to a 10% duty cycle, the IEDF graph 306 corresponds to a 15% duty cycle, and the IEDF graph 308 corresponds to a 20% duty cycle. The IEDF graphs 302-308 show a bimodal character, with distinct low and high energy peaks formed due to the oscillating potential of the substrate. In some embodiments, the high energy peak may have greater intensity than the low energy peak.

In some embodiments, the IEDF measurements to generate the IEDF graphs 302-308 may be obtained using an ion energy analyzer installed in the plasma processing system 10 (see FIG. 1), as described above. By analyzing the IEDF graphs 302-308, process engineers can determine how changes in plasma parameters affect the energy distribution of ions striking the substrate surface. In various embodiments, understanding and controlling the IEDF allow for achieving desired process results, as the energy distribution of ions impacts etch rate, profile, and uniformity in plasma etching processes, as well as deposition characteristics in plasma-enhanced deposition processes.

FIG. 4 illustrates a schematic diagram of an artificial neural network (ANN) 400, in accordance with some embodiment. In some embodiments, to obviate the need for measurement of IEDFs during plasma processing, particularly during production plasma processing, the ANN 400 may be utilized to predict the entire IEDF or select features of the IEDF from various parameters of a plasma process performed by a plasma processing system (e.g., plasma processing system 10 of FIG. 1). The ANN 400 serves as a means for algebraically transforming known input parameters of the plasma process into predicted features of the IEDF, thereby providing the IEDF features necessary for plasma process control, even if the IEDF itself has not been directly measured. The ANN 400 may be implemented by a controller (e.g., controller 170A or 170B of FIG. 1), which may be a part of or external to the plasma processing system (e.g., plasma processing system 10 of FIG. 1).

In some embodiments, a controller implementing the ANN 400 may include a data collection module that continuously gathers operating parameters during processing. This collected data can be used for periodic retraining of the ANN 400 to account for tool drift, chamber condition changes, or process modifications. In some embodiments, the controller may implement multiple ANNs, with each ANN being configured for different process recipes or chamber configurations of the plasma processing system (e.g., plasma processing system 10 of FIG. 1). For example, a separate ANN may be used for each gas chemistry, enabling more accurate predictions for specific process conditions without requiring a single complex ANN to handle all possible variations.

The ANN 400 includes an input layer 402, an output layer 404, and one or more hidden layers 406 arranged between the input layer 402 and the output layer 404. In the illustrated embodiment, the ANN 400 includes multiple hidden layers designated as hidden layer 406-1, hidden layer 406-2, and additional hidden layers up to hidden layer 406-N, where N represents the total number of hidden layers in the ANN 400. Each layer of the ANN 400 may include one or more nodes, which may be also referred to as neurons.

The input layer 402 includes multiple nodes for receiving input data (e.g., plasma process parameters) for processing by the ANN 400. As shown in the FIG. 4, the input layer 402 includes nodes 408-1, 408-2, and additional nodes up to node 408-P, where P represents the total number of nodes in the input layer 402. Each node in the input layer 402 can receive a different feature or element of the input data (e.g., different plasma process parameters).

The hidden layers 406 process the data received from the input layer 402 through various transformations. The hidden layer 406-1 includes nodes 412-1, 412-2, and additional nodes up to node 412-K, where K represents the total number of nodes in the hidden layer 406-1. Similarly, the hidden layer 406-2 includes nodes 414-1, 414-2, and additional nodes up to node 414-L, where L represents the total number of nodes in the hidden layer 406-2. The hidden layer 406-N includes nodes 416-1, 416-2, and additional nodes up to node 416-M, where M represents the total number of nodes in the hidden layer 406-N.

The output layer 404 produces the final output (e.g., predicted features of the IEDF) of the ANN 400 based on the processed data from the hidden layers 406. The output layer 404 includes nodes 410-1, 410-2, and additional nodes up to node 410-Q, where Q represents the total number of nodes in the output layer 404.

In some embodiments, each node of the ANN 400 may receive multiple inputs defined as a vector X, from other nodes or an ANN input, and transforms the input vector X into an output Y determined as Y=F(W·X+b), where W represents weights and b is the bias of each node. A nonlinear activation function F may be applied to the calculated output of every node, and the output of the node is then passed to the next layer of the ANN 400, or becomes an ANN output in the case of an output layer node. In a fully-connected ANN, such as the ANN 400 shown in FIG. 4, all node outputs of a previous layer are applied to all nodes of a next layer. Weights W and bias parameters b for all nodes of the ANN 400 are collectively known as ANN parameters, and these parameters are determined during an ANN training process. The activation function F may be a nonlinear function such as a sigmoid function, a hyperbolic tangent function, or a rectified linear unit (ReLU) function. The nonlinear activation function applied to outputs of nodes dramatically increases the prediction space of an ANN over what would otherwise be a space mapped by successive linear transformations only.

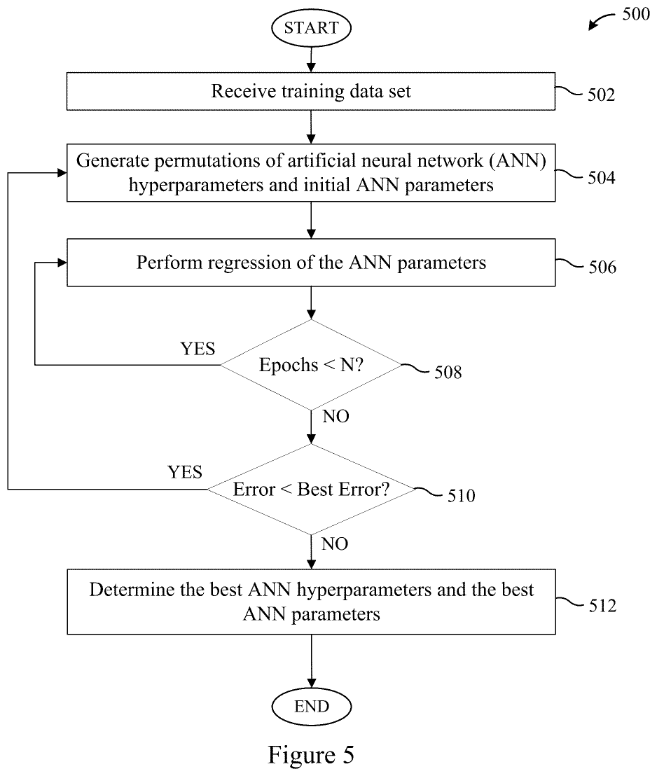

FIG. 5 is a flow diagram of a method 500 for training of an artificial neural network (ANN), in accordance with some embodiments. Although shown in a particular sequence, it should be appreciated that the steps of the method 500 may be performed in any suitable sequence. In some embodiments, the method 500 may be performed by a controller when executing instructions stored in a non-transitory computer-readable storage medium. The controller may be a part of a plasma processing system (e.g., plasma processing system 10 of FIG. 1), or may be a separate computer, server, or controller.

The method 500 begins with step 502, where the controller receives training data set. The training data set may comprise a set of operating parameters of a plasma processing system (e.g., plasma processing system 10 of FIG. 1), and a set of IEDF features corresponding to these operating parameters. The training data set may comprise a plurality of samples, each sample including a pair of i operating parameters and corresponding j IEDF features. The operating parameters of the plasma processing system may include setpoints from process recipes being run for generating the training data set, parameters measured by sensors of the plasma processing system, or simulated parameters from first principles or statistical simulations of the plasma process in the plasma processing system. The corresponding IEDF features of the training data set can either be features measured using, for example, an ion energy analyzer, or they can be simulated IEDF features from, for example, simulations of the IEDFs performed using the corresponding operating parameters. The training data set is provided as input to an ANN (e.g., ANN 400 of FIG. 4) to be trained.

In step 504, after receiving the training data set, the controller generates permutations of ANN hyperparameters and initial ANN parameters. The ANN hyperparameters may include learning rates, number of nodes (also referred to as neurons) per layer of the ANN, and other parameters that govern the ANN training process. The initial ANN parameters include initial guesses of weights W and biases b for all nodes in the ANN.

In step 506, the method 500 performs regression of the ANN parameters. This involves an iterative process that adjusts the weights and biases of all nodes of the ANN to minimize a loss function, typically using a gradient descent algorithm. The backpropagation algorithm calculates the sensitivity of the loss function to each individual parameter and adjusts them accordingly. The loss function may include the mean square error (MSE) or mean absolute error (MAE) calculated at each iteration between the predicted output of the ANN, at a current training epoch, and the IEDF features of the training data set.

In step 508, the controller determines whether the number of training epochs is less than a predetermined value N. In response to determining at step 508 that the number of training epochs is less than the predetermined value N, the method 500 proceeds back to step 506. In response to determining at step 508 that the number of training epochs equals the predetermined value N, the method 500 proceeds to step 510.

In step 510, the controller evaluates whether the current error is less than the best error achieved so far. In response to determining at step 510 that the current error is less than the best error achieved so far, indicating an improvement in the ANN performance, the method 500 proceeds back to step 504 to generate new permutations of ANN hyperparameters and initial ANN parameters. In response to determining at step 510 that the current error is not less than the best error achieved so far, the method 500 proceeds to step 512.

In step 512, the controller determines the ANN hyperparameters and ANN parameters that yielded the best performance. These optimized parameters are then retained for future predictions of IEDF features in plasma processing applications. The set of operating parameters of the plasma processing system used for training (and later prediction) may include at least one of source RF power, substrate RF bias power, substrate bias potential, substrate bias pulse time t_{B}, substrate bias pulse potential V_{B}, bias pulse lag time Δt, source pulse time t_{S}, pulse period τ, chamber pressure, flow rate of a process gas introduced into a plasma process chamber, etc.

In some embodiments, the method 500 employs Bayesian optimization for ANN hyperparameter tuning, which is particularly effective for training with sparse datasets typical of laboratory measurements. This approach allows the ANN to achieve good prediction accuracy even with limited training data, making it practical for plasma process development and control applications where extensive data collection may be impractical or costly.

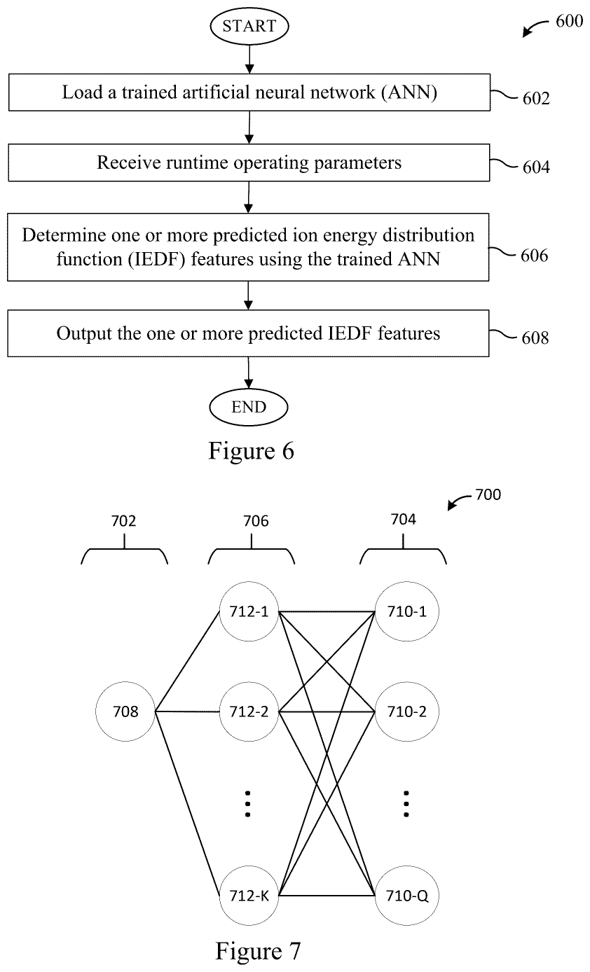

FIG. 6 is a flow diagram of a method 600 for utilizing a trained artificial neural network (ANN) for prediction of ion energy distribution function (IEDF) features, during, for example, a plasma processing step in a plasma processing system (e.g., plasma processing system 10 of FIG. 1), in accordance with some embodiments. Although shown in a particular sequence, it should be appreciated that the steps of the method 600 may be performed in any suitable sequence. In some embodiments, the method 600 may be performed by a controller when executing instructions stored in a non-transitory computer-readable storage medium. The controller may be a part of the plasma processing system (e.g., plasma processing system 10 of FIG. 1), or may be a separate computer, server, or controller.

The method 600 begins with step 602, where the controller loads a trained ANN. In some embodiments, an ANN (e.g., ANN 400 of FIG. 4) may be trained using the method 500 as described above with reference to FIG. 5.

In step 604, the controller receives runtime operating parameters of a plasma processing system (e.g., plasma processing system 10 of FIG. 1) at any desired point during a plasma process. The runtime operating parameters correspond to parameters used in ANN training. The runtime operating parameters may include process setpoints from the current recipe being executed, such as source RF power, substrate RF bias power, substrate bias potential, substrate bias pulse time, substrate bias pulse potential, bias pulse lag time, source pulse time, pulse period, chamber pressure, or flow rates of process gases. Alternatively, the runtime operating parameters may include measurements from sensors installed on the plasma processing system, such as voltage measurements from a voltage probe (e.g., voltage probe 172 of FIG. 1). In other embodiments, the runtime operating parameters may also include simulated parameters from computational models that match the current process conditions.

In step 606, after receiving the runtime operating parameters, the controller determines one or more predicted IEDF features using the trained ANN. In this step, the runtime operating parameters collected in step 604 are provided as inputs to the trained ANN, which then performs a forward pass through its layers to calculate predictions of IEDF features. The predicted IEDF features may include the entire IEDF spectrum or specific characteristics of the IEDF such as peak locations, peak intensities, mean intensity, mean ion energy, maximum intensity, width of the IEDF, or center energy of the IEDF.

In step 608, the controller outputs the one or more predicted IEDF features. The predicted IEDF features can be used for various purposes, including process development, process control, setting and altering recipe parameters during processing, and performing fault detection. In some embodiments, the predicted IEDF features may be used to adjust process parameters in real-time to maintain desired process outcomes such as etch rate, etch profile, etch uniformity, deposition rate, or deposition uniformity.

By providing rapid predictions of IEDF features without the need for direct measurement using ion energy analyzers, the method 600 enables more effective process control and monitoring in production environments where direct IEDF measurements may be impractical or disruptive to the process.

FIG. 7 illustrates a schematic diagram of an artificial neural network (ANN) 700, in accordance with some embodiment. The ANN 700 is configured for processing sparse datasets while maintaining high prediction accuracy. The ANN 700 may be implemented by a controller (e.g., controller 170A or 170B of FIG. 1), which may be a part of or external to the plasma processing system (e.g., plasma processing system 10 of FIG. 1).

In some embodiments, a controller implementing the ANN 700 may include a data collection module that continuously gathers operating parameters during processing. This collected data can be used for periodic retraining of the ANN 700 to account for tool drift, chamber condition changes, or process modifications. In some embodiments, the controller may implement multiple ANNs, with each ANN being configured for different process recipes or chamber configurations of the plasma processing system (e.g., plasma processing system 10 of FIG. 1). For example, a separate ANN may be used for each gas chemistry, enabling more accurate predictions for specific process conditions without requiring a single complex ANN to handle all possible variations.

The ANN 700 comprises an input layer 702, a hidden layer 706, and an output layer 704 arranged in a feed-forward configuration. The input layer 702 comprises of a single input node 708 that receives a single plasma processing parameter, while keeping all other processing parameter constant. In one embodiment, the single plasma processing parameter is bias pulse time t B. The single-parameter input design reflects the focused approach of the ANN 700, which targets a specific parameter rather than attempting to process numerous variables simultaneously.

The hidden layer 706 comprises multiple nodes 712-1, 712-2, through 712-K, where K represents the total number of nodes in the hidden layer 706. In one embodiment, the hidden layer 706 comprises 30 nodes, each utilizing a sigmoid activation function. In some embodiments, the moderate number of hidden nodes provides sufficient model complexity to capture the nonlinear relationships between the input parameter and the IEDF features without requiring excessive training data or computational resources.

The output layer 704 comprises of multiple nodes 710-1, 710-2, through 710-Q, where Q represents the total number of output nodes in the output layer 704. In one embodiment, the output layer 704 comprises 49 nodes, each corresponding to a specific point in the predicted IEDF spectrum (approximated by 49 points from low to high ion energy). These output nodes collectively represent the IEDF spectrum as a series of ion energy-intensity pairs. In some embodiments, for ANN training purposes, measured IEDFs can be filtered, subsampled, or binned to reduce the number of predicted points per IEDF, thereby reducing training and prediction computational load and computational efficiency. In some embodiments, the ANN 700 enables efficient prediction of IEDF spectra with reduced computational requirements, making it suitable for implementation on standard computing hardware without specialized accelerators.

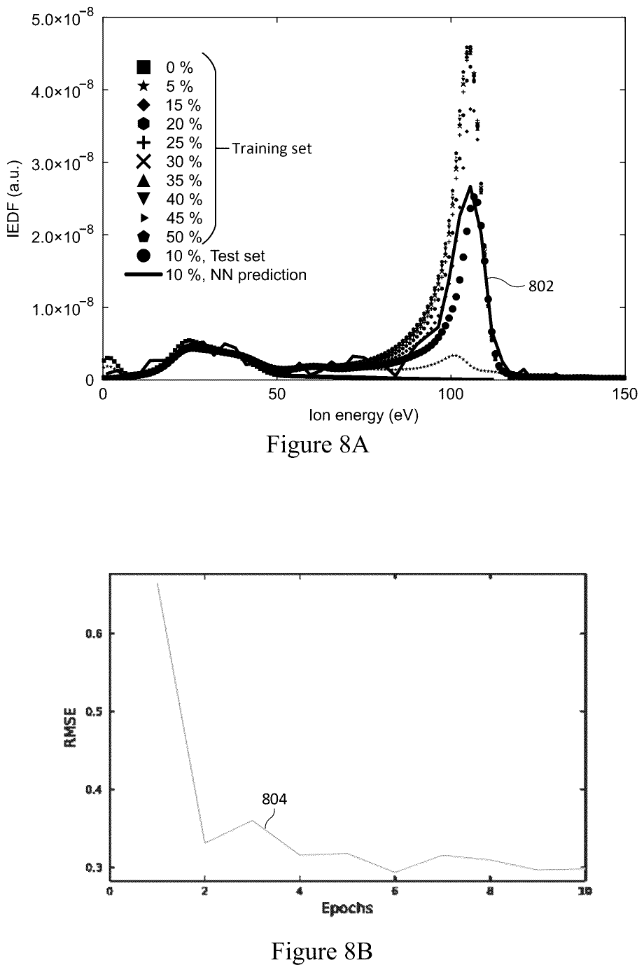

FIG. 8A illustrates ion energy distribution function (IEDF) prediction results obtained using the artificial neural network (ANN) 700 described in FIG. 7, in accordance with some embodiments. The graph in FIG. 8 displays three sets of data: training set, test set, and ANN prediction results. The horizontal axis represents ion energy, while the vertical axis represents the intensity of the ion energy distribution.

The training set data points represent the measured IEDF spectra at various duty cycles that were used to train the ANN. In particular, the IEDF spectrum depicted using “filled squares” as data labels correspond to a 0% duty cycle, the IEDF spectrum depicted using “filled stars” as data labels correspond to a 5% duty cycle, the IEDF spectrum depicted using “filled diamonds” as data labels correspond to a 15% duty cycle, the IEDF spectrum depicted using “filled hexagons” as data labels correspond to a 20% duty cycle, the IEDF spectrum depicted using “+'s” as data labels correspond to a 25% duty cycle, the IEDF spectrum depicted using “X's” as data labels correspond to a 30% duty cycle, the IEDF spectrum depicted using “up-oriented filled triangles” as data labels corresponded to a 35% duty cycle, the IEDF spectrum depicted using “down-oriented filled triangles” as data labels correspond to a 40% duty cycle, the IEDF spectrum depicted using “right-oriented filled triangles” as data labels correspond to a 45% duty cycle, and the IEDF spectrum depicted using “filled pentagons” as data labels correspond to a 50% duty cycle.

The test set data points represent measured IEDF data that was deliberately excluded from the training process to evaluate the ANN's prediction capability. In particular, the IEDF spectrum depicted using “filled circles” as data labels correspond to a 10% duty cycle.

The graph 802 (shown as a continuous line) represents the IEDF spectrum predicted by the ANN 700 for the same plasma conditions (i.e., 10% duty cycle) as the test set. In the illustrated embodiment, a mean absolute percentage error (MAPE) of 3% is achieved between the predicted IEDF spectrum and the test set.

FIG. 8B illustrates a graph 804 of root mean square error (RMSE) during training of an artificial neural network (ANN) 700 described in FIG. 7, in accordance with some embodiments. In particular, the graph 804 shows the monotonically decreasing RMSE on the vertical axis plotted against the number of training epochs on the horizontal axis. The monotonically decreasing RMSE curve indicates that the training process is converging properly without overfitting.

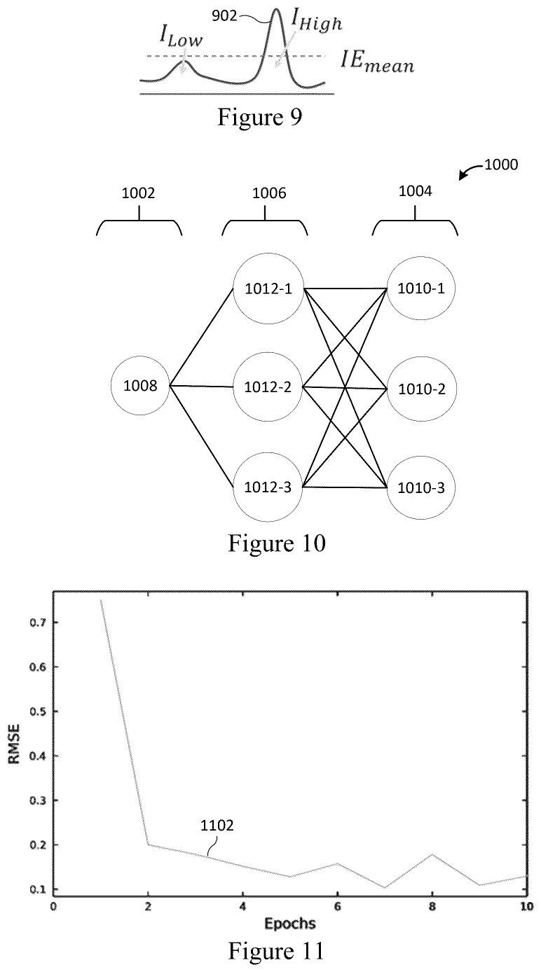

FIG. 9 illustrates ion energy distribution function (IEDF) features selected for prediction using artificial neural networks (ANNs) in plasma processing applications, in accordance with some embodiments. In particular, FIG. 9 provides a visual representation of various characteristics extracted from IEDF spectra.

The graph 902 depicts an IEDF spectrum with ion energy on the horizontal axis and intensity on the vertical axis. The IEDF spectrum displays a characteristic bimodal distribution, with two distinct peaks at different energy levels. Three IEDF features shown in the FIG. 9 the low peak intensity (I_{Low}), the high peak intensity (I_{High}), and the mean ion energy (IEₘₑₐₙ). The low energy peak corresponds to ions that reach a substrate when the bias potential is at or near its minimum value, while the high energy peak represents ions that arrive when the bias potential is at or near its maximum. The mean ion energy represents the average energy across the entire distribution. Other IEDF features (not shown) may include the low peak ion energy, the high peak ion energy, the center ion energy, as well as other desired parameters.

The IEDF features provide a more efficient approach to characterizing the IEDF compared to predicting the entire spectrum. By focusing on the selected IEDF features, the ANN can be simplified with fewer output nodes, enabling faster training, more efficient prediction, and reduced computational requirements, making this approach well-suited for real-time process monitoring and control applications in semiconductor manufacturing environments.

FIG. 10 illustrates a schematic diagram of an artificial neural network (ANN) 1000 configured for predicting ion energy distribution function (IEDF) features of FIG. 9 in plasma processing applications, in accordance with some embodiments. The ANN 1000 represents a more focused approach compared to the ANN 700 shown in FIG. 7, targeting specific IEDF features rather than the entire IEDF spectrum. The ANN 1000 may be implemented by a controller (e.g., controller 170A or 170B of FIG. 1), which may be a part of or external to the plasma processing system (e.g., plasma processing system 10 of FIG. 1).

In some embodiments, a controller implementing the ANN 1000 may include a data collection module that continuously gathers operating parameters during processing. This collected data can be used for periodic retraining of the ANN 1000 to account for tool drift, chamber condition changes, or process modifications. In some embodiments, the controller may implement multiple ANNs, with each ANN being configured for different process recipes or chamber configurations of the plasma processing system (e.g., plasma processing system 10 of FIG. 1). For example, a separate ANN may be used for each gas chemistry, enabling more accurate predictions for specific process conditions without requiring a single complex ANN to handle all possible variations.

The ANN 1000 comprises an input layer 1002, a hidden layer 1006, and an output layer 1004, arranged in a feed-forward configuration. The input layer 1002 comprises of a single input node 1008 that receives a single plasma processing parameter, while keeping all other processing parameter constant. In one embodiment, the single plasma processing parameter is bias pulse time t B, the single-parameter input design reflects the focused approach of the ANN 1000, which targets a specific parameter rather than attempting to process numerous variables simultaneously.

The hidden layer 1006 comprises three nodes 1012-1, 1012-2, and 1012-3, each utilizing a sigmoid activation function. In this implementation, the hidden layer 1006 has fewer nodes compared to the ANN 700 in FIG. 7, as predicting specific IEDF features requires less complexity than predicting the entire IEDF spectrum. This reduction in network size further improves training efficiency and reduces computational requirements.

The output layer 1004 comprises three nodes 1010-1, 1010-2, and 1010-3, each corresponding to a specific IEDF feature as illustrated in FIG. 9. In one embodiment, the node 1010-1 may correspond to the low peak intensity (I_{Low}), the node 1010-2 may correspond to the high peak intensity (I_{High}), and the node 1010-3 may correspond to the mean ion energy (IEₘₑₐₙ).

This feature-focused network architecture enables more efficient training and prediction compared to full-spectrum prediction networks. By targeting specific IEDF features, the ANN 1000 provides practical utility for plasma process development and optimization while minimizing computational requirements. This approach is particularly valuable in production environments where rapid prediction of process indicators is needed for maintaining process stability and yield.

FIG. 11 illustrates a graph 1102 showing a root mean square error (RMSE) progression during the training of the artificial neural network (ANN) 1000 described in FIG. 10, in accordance with some embodiments. In particular, the graph 1102 shows the monotonically decreasing RMSE on the vertical axis plotted against the number of training epochs on the horizontal axis. The monotonically decreasing RMSE curve indicates that the training process is converging properly without overfitting.

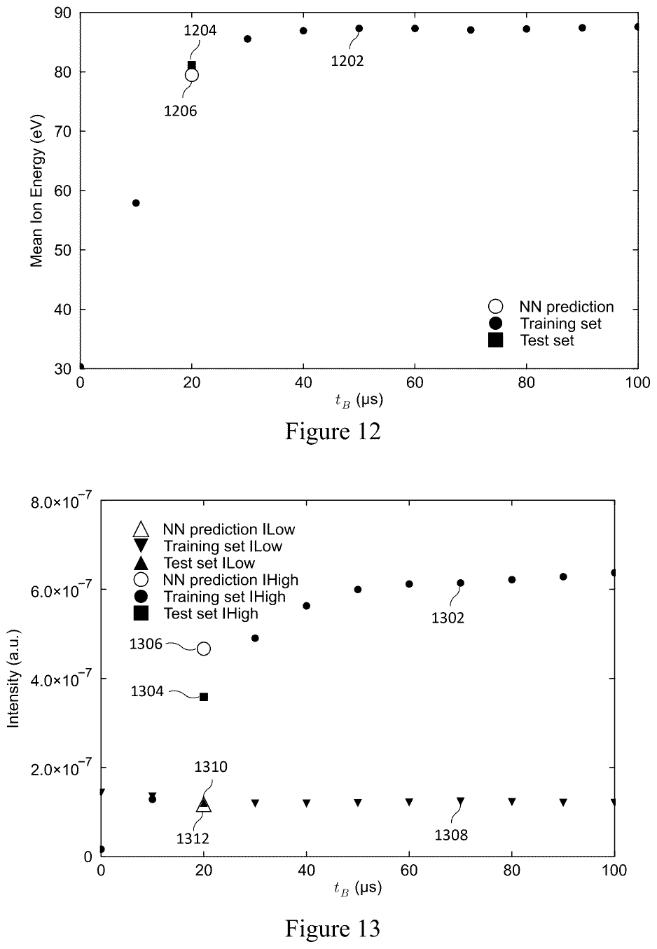

FIG. 12 illustrates a mean ion energy (IEₘₑₐₙ) predicted using the artificial neural network (ANN) 1000 described in FIG. 10, in accordance with some embodiments. In particular, the graph in FIG. 12 displays three distinct datasets plotted against the bias pulse time (t_{B}) on the horizontal axis, with mean ion energy values on the vertical axis. The three datasets include the training set 1202, the test set 1204, and the predicted set 1206. In the illustrated embodiment, MAPE of 1% is achieved for IEₘₑₐₙ predictions.

FIG. 13 illustrates high and low peak intensities predicted using an artificial neural network (ANN) 1000 described in FIG. 10, in accordance with some embodiments. In particular, the graph in FIG. 13 displays multiple datasets plotted against the bias pulse time (t_{B}) on the horizontal axis, with intensity values on the vertical axis. Two distinct datasets are shown, representing the low peak intensity (I_{Low}) and high peak intensity (I_{High}) of the IEDF spectrum.

For the high peak intensity (I_{High}), FIG. 13 shows the training set 1302, the test set 1304, and the predicted set 1306. In the illustrated embodiment, MAPE of 6% is achieved for I_{High} predictions.

For the low peak intensity (I_{Low}), FIG. 13 shows the training set 1308, the test set 1310, and the predicted set 1312. In the illustrated embodiment, MAPE of 1% is achieved for I_{Low} predictions.

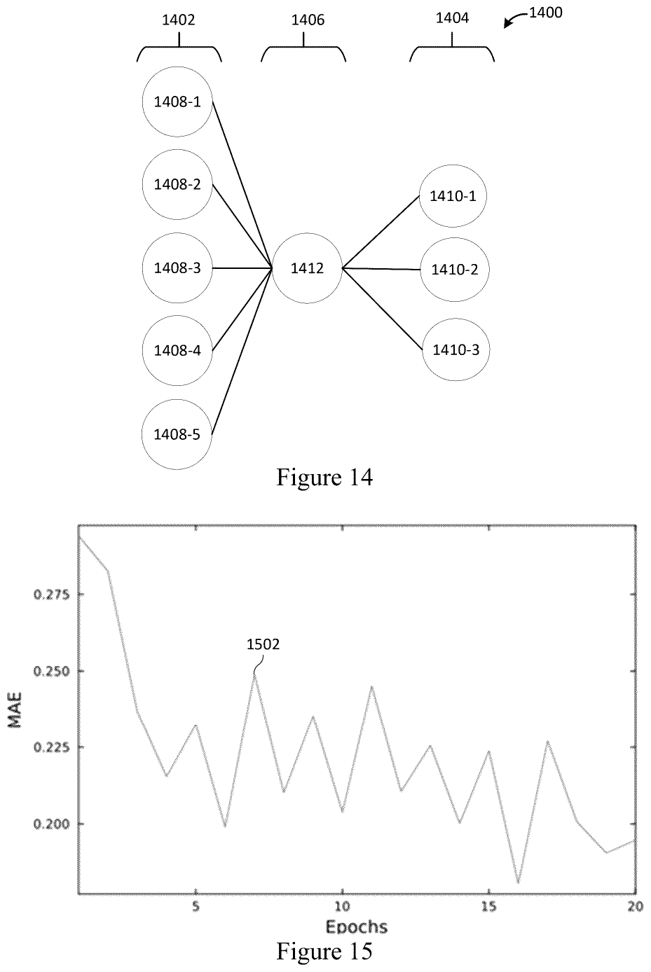

FIG. 14 illustrates a schematic diagram of a linear autoencoder artificial neural network (ANN) 1400, in accordance with some embodiments. The linear autoencoder ANN 1400 is designed to perform dimensionality reduction and identify the most significant relationships between input parameters and output features. The linear autoencoder ANN 1400 may be implemented by a controller (e.g., controller 170A or 170B of FIG. 1), which may be a part of or external to the plasma processing system (e.g., plasma processing system 10 of FIG. 1).

In some embodiments, a controller implementing the linear autoencoder ANN 1400 may include a data collection module that continuously gathers operating parameters during processing. This collected data can be used for periodic retraining of the linear autoencoder ANN 1400 to account for tool drift, chamber condition changes, or process modifications. In some embodiments, the controller may implement multiple ANNs, with each ANN being configured for different process recipes or chamber configurations of the plasma processing system (e.g., plasma processing system 10 of FIG. 1). For example, a separate ANN may be used for each gas chemistry, enabling more accurate predictions for specific process conditions without requiring a single complex ANN to handle all possible variations.

The linear autoencoder ANN 1400 comprises an input layer 1402, a hidden layer 1406, and an output layer 1404, arranged in a feed-forward configuration. The input layer 1402 comprises five input nodes 1408-1, 1408-2, 1408-3, 1408-4, and 1408-5, each corresponding to a different plasma processing parameter. These parameters include the substrate bias pulse time t_{B}, the substrate bias pulse potential V_{B}, the bias pulse lag time Δt, the source pulse time t_{S}, and the pulse period τ. The multi-parameter input design allows the linear autoencoder ANN 1400 to analyze the relative importance of various process parameters simultaneously.

In one embodiment, the input node 1408-1 corresponds to the substrate bias pulse time t_{B}, the input node 1408-2 corresponds to the substrate bias pulse potential V_{B}, the input node 1408-3 corresponds to the bias pulse lag time Δt, the input node 1408-4 corresponds to the source pulse time t_{S}, and the input node 1408-5 corresponds to the pulse period τ.

The hidden layer 1406 comprises a single hidden node 1412, creating a “bottleneck” in the network architecture. This bottleneck allows the linear autoencoder ANN 1400 to distill the information from multiple input parameters into a minimal representation, effectively performing dimensionality reduction. The single hidden node 1412 utilizes a rectified linear unit (ReLU) activation function, which has been found to provide better convergence for this application compared to sigmoid or hyperbolic tangent functions.

The output layer 1404 comprises three nodes 1410-1, 1410-2, and 1410-3, each corresponding to a specific IEDF feature. These features may include the maximum ion energy, the high peak center ion energy, and the high peak intensity (I_{High}). In one embodiment, the node 1410-1 corresponds to the maximum ion energy, the node 1410-2 corresponds to the high peak center ion energy, and the node 1410-3 corresponds to the high peak intensity (I_{High}).

A distinctive feature of linear autoencoder ANN 1400 is that the weights connecting the input layer 1402 to the hidden layer 1406 provide valuable information about the relative importance of each input parameter in determining the output IEDF features. After training, the magnitude of these weights indicates which plasma parameters have the strongest influence on the IEDF characteristics, enabling a form of principal component analysis (PCA) without requiring additional computational steps. Furthermore, mathematical methods exist to convert the weights W of a trained linear autoencoder ANN into actual principal components, thus allowing one to perform true PCA of the input operating parameters and the output IEDF features.

For example, the weights vector W of the single hidden node 1412 of the trained linear autoencoder ANN 1400 of FIG. 14 are (0.33, −4.33, −0.62, 0.05, −0.72) for the five input operating parameters (t_{B}, V_{B}, Δt, t_{S}, τ), respectively. This means that the predicted IEDF features have the strongest dependence on the substrate bias pulse potential V_{B} represented by the largest weight −4.33. Conversely, the very low magnitude of the fourth weight, 0.05, indicates that the predicted IEDF features will exhibit a very weak dependence on the source pulse time t_{S}. By identifying which parameters have the strongest influence on IEDF features, this approach enables more efficient process development and optimization, reducing the need for extensive experimental trials and accelerating the path to stable, high-yield processes.

FIG. 15 illustrates a graph 1502 showing a mean absolute error (MAE) progression during the training of the linear autoencoder artificial neural network (ANN) 1400 described in FIG. 14, in accordance with some embodiments. In particular, the graph 1502 shows the monotonically decreasing MAE on the vertical axis plotted against the number of training epochs on the horizontal axis. The monotonically decreasing MAE curve indicates that the training process is converging properly without overfitting.

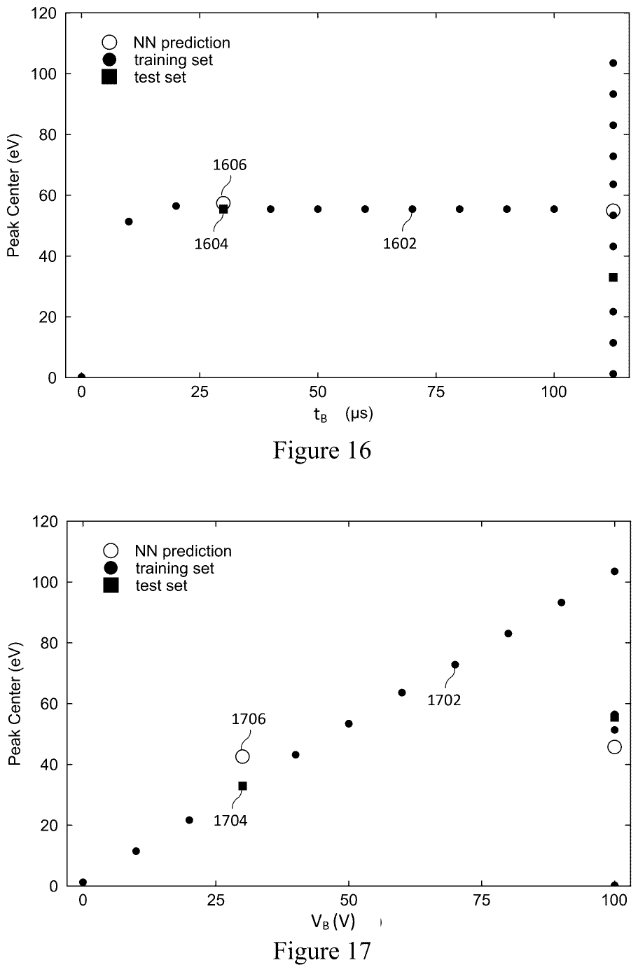

FIG. 16 illustrates prediction results for the high peak center ion energy of the ion energy distribution function (IEDF) obtained using the linear autoencoder artificial neural network (ANN) 1400 described in FIG. 14, in accordance with some embodiments. In particular, the graph in FIG. 16 displays three datasets plotted against the substrate bias pulse time (t_{B}) on the horizontal axis, with high peak center ion energy values on the vertical axis. The three datasets include training set 1602, test set 1604, and the predicted set 1606.

The high peak center ion energy shows minor variations across the entire range of bias pulse times examined, suggesting that this IEDF feature has a weak dependence on bias pulse time. This finding aligns with the weights analysis of the linear autoencoder ANN 1400 described above with reference to FIG. 14, which identified the substrate bias pulse time (t_{B}) as having weight magnitude of 0.33. This weak dependency is particularly significant from a process control perspective, as it indicates that adjusting the bias pulse time alone would not be an effective strategy for controlling the high peak center ion energy in this plasma process. Instead, other parameters with stronger influence, as identified by weight analysis of the linear autoencoder ANN 1400, would be more suitable control knobs.

FIG. 17 illustrates prediction results for the high peak center ion energy of the ion energy distribution function (IEDF) obtained using the linear autoencoder artificial neural network (ANN) 1400 described in FIG. 14, in accordance with some embodiments. In particular, the graph in FIG. 17 displays three datasets plotted against the substrate bias pulse potential (V_{B}) on the horizontal axis, with high peak center ion energy values on the vertical axis. The three datasets include training set 1702, test set 1704, and the predicted set 1706.

This graph reveals a strong, nearly linear relationship between the high peak center ion energy and the bias pulse potential. As the bias pulse potential increases, the high peak center ion energy increases proportionally, indicating a direct and significant dependency. This strong relationship aligns with the weights analysis of the linear autoencoder ANN 1400 described above with reference to FIG. 14, which identified bias pulse potential as having the largest weight magnitude −4.33 among the five input parameters.

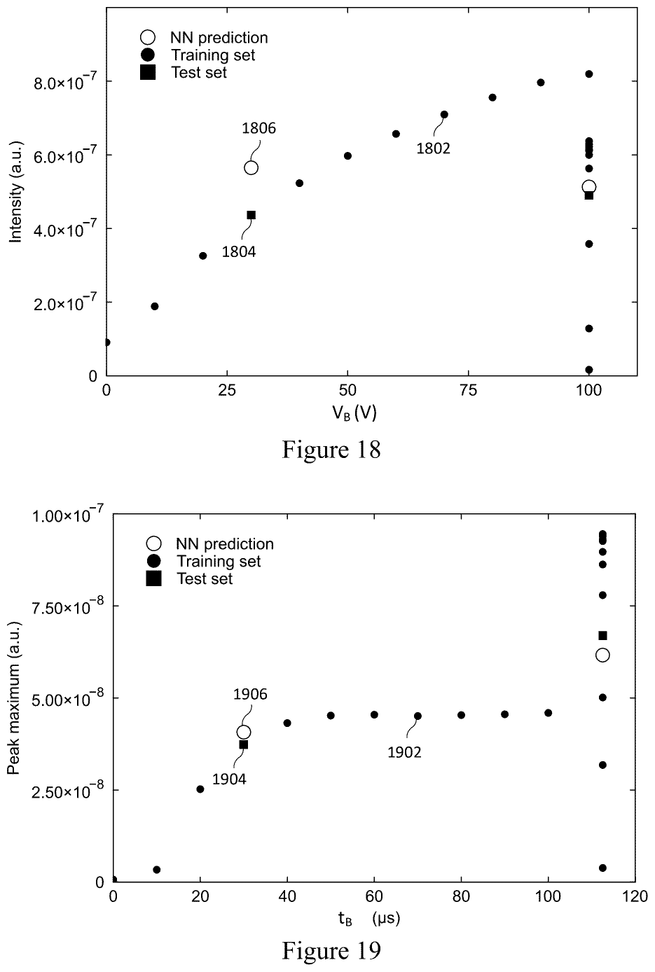

FIG. 18 illustrates prediction results for the high peak intensity (I_{High}) of the ion energy distribution function (IEDF) obtained using the linear autoencoder artificial neural network (ANN) 1400 described in FIG. 14, in accordance with some embodiments. The graph in FIG. 18 displays three datasets plotted against the substrate bias pulse potential (V_{B}) on the horizontal axis, with high peak intensity values on the vertical axis. The three datasets include training set 1802, test set 1804, and the predicted set 1806.

This graph reveals a strong, nearly linear relationship between the high peak intensity (I_{High}) and the bias pulse potential, with the intensity increasing as the bias pulse potential increases. This strong relationship aligns with the weights analysis of the linear autoencoder ANN 1400 described above with reference to FIG. 14, which identified bias pulse potential as having the largest weight magnitude −4.33 among the five input parameters.

FIG. 19 illustrates prediction results for the peak maximum intensity of the ion energy distribution function (IEDF) obtained using the linear autoencoder artificial neural network (ANN) 1400 described in FIG. 14, in accordance with some embodiments. The graph in FIG. 19 displays three datasets plotted against the substrate bias pulse time (t_{B}) on the horizontal axis, with peak maximum intensity values on the vertical axis. The three datasets include training set 1902, test set 1904, and the predicted set 1906.

The graph reveals a moderate dependency of the peak maximum intensity on the bias pulse time. This moderate relationship aligns with the weights analysis of the linear autoencoder ANN 1400 described above with reference to FIG. 14, which identified the substrate bias pulse time (t_{B}) as having a weight magnitude of 0.33.

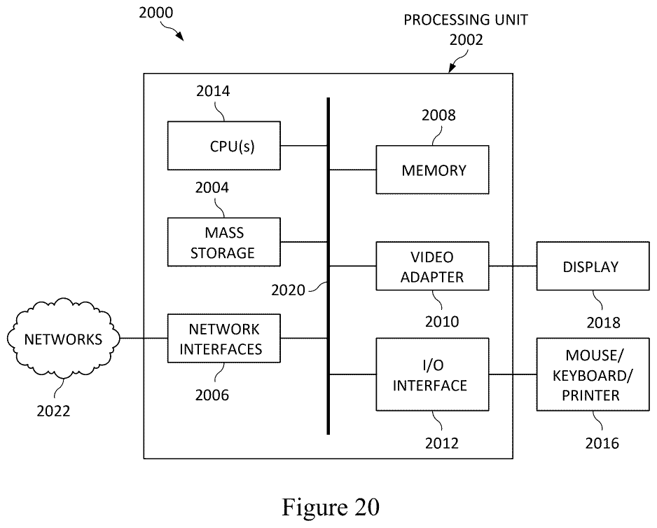

FIG. 20 is a block diagram of a computing system 2000 that may be used for implementing the devices and methods disclosed herein. In some embodiments, the computing system 2000 may be used for implementing controllers 170A and 170B of FIG. 1. In other embodiments, the computing system 2000 may be used for implementing ANNs (e.g., ANNs 400, 700, 1000, and 1400 of FIGS. 4, 7, 10, and 14, respectively) disclosed herein. In yet other embodiments, the computing system 2000 may be used for implementing methods 500 and 600 of FIGS. 5 and 6, respectively.

The computing system 2000 includes a processing unit 2002. The processing unit includes one or more central processing units (CPUs) 2014, memory 2008, and may further include a mass storage device 2004, a video adapter 2010, and an I/O interface 2012 connected to a bus 2020.

The bus 2020 may be one or more of any type of several bus architectures including a memory bus or memory controller, a peripheral bus, or a video bus. Each of the one or more CPUs 2014 may comprise any type of electronic data processor. The memory 2008 may comprise any type of non-transitory system memory such as static random-access memory (SRAM), dynamic random-access memory (DRAM), synchronous DRAM (SDRAM), read-only memory (ROM), or a combination thereof. In an embodiment, the memory 2008 may include ROM for use at boot-up, and DRAM for program and data storage for use while executing programs.

The mass storage device 2004 may comprise any type of non-transitory computer-readable storage device (or medium) configured to store instructions, data, programs, and other information and to make the instructions, data, programs, and other information accessible via the bus 2020. The mass storage device 2004 may comprise, for example, one or more of a solid-state drive, hard disk drive, a magnetic disk drive, or an optical disk drive.

In one embodiment, the one or more CPUs 2014, when executing instructions stored in the mass storage device 2004, perform one or more steps of the method 500 of FIG. 5. In another embodiment, the one or more CPUs 2014, when executing instructions stored in the mass storage device 2004, performs one or more steps of the method 600 of FIG. 6.

The video adapter 2010 and the I/O interface 2012 provide interfaces to couple external input and output devices to the processing unit 2002. As illustrated, examples of input and output devices include a display 2018 coupled to the video adapter 2010 and a mouse, keyboard, or printer 2016 coupled to the I/O interface 2012. Other devices may be coupled to the processing unit 2002, and additional or fewer interface cards may be utilized. For example, a serial interface such as Universal Serial Bus (USB) (not shown) may be used to provide an interface for an external device.

The processing unit 2002 also includes one or more network interfaces 2006, which may comprise wired links, such as an Ethernet cable, or wireless links to access different networks. The network interfaces 2006 allow the processing unit 2002 to communicate with remote units via the networks. In an embodiment, the processing unit 2002 is coupled to a local-area network or a wide-area network for data processing and communications with remote devices, such as other processing units, the Internet, or remote storage facilities.

Example embodiments of the disclosure are described below. Other embodiments can also be understood from the entirety of the specification as well as the claims filed herein.

### Example 1

A method including: receiving a training data set including: one or more operating parameters of a plasma processing system, where the one or more operating parameters include at least one process setpoint from a process recipe, at least one measured operating parameter, or at least one simulated operating parameter; and a plurality of ion energy distribution function (IEDF) features corresponding to the one or more operating parameters, where the plurality of IEDF features includes at least one measured IEDF feature or at least one simulated IEDF feature; and training an artificial neural network (ANN) using the one or more operating parameters as input, and the plurality of IEDF features as output, where the ANN includes: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes.

### Example 2

The method of example 1, where the input layer includes a single input node.

### Example 3

The method of example 1, where the input layer includes five input nodes.

### Example 4

The method of any of examples 1 to 3, where the output layer includes three output nodes.

### Example 5

The method of any of examples 1 to 4, where the single hidden layer is a fully-connected layer.

### Example 6

The method of any of examples 1 to 5, where the single hidden layer includes three hidden nodes.

### Example 7

The method of any of examples 1 to 6, where the single hidden layer includes thirty hidden nodes.

### Example 8

The method of any of examples 1 to 5, where the single hidden layer includes a single hidden node.

### Example 9

The method of example 8, further including: performing principal component analysis (PCA), utilizing trained weights of the single hidden node, to determine a dependence of the IEDF features on the operating parameters of the plasma processing system.

### Example 10

The method of any of examples 8 and 9, where the ANN is trained using a rectified linear unit (ReLU) activation function for the single hidden node.

### Example 11

The method of any of examples 1 to 5, where the single hidden layer includes a plurality of hidden nodes and the ANN is trained using a sigmoid activation function for the plurality of hidden nodes.

### Example 12

The method of any of examples 1 to 11, further including: receiving runtime operating parameters of the plasma processing system; and predicting IEDF values utilizing the ANN with the runtime operating parameters as input.

### Example 13

The method of example 12, further including: setting or altering the runtime operating parameters of the plasma processing system, based on the predicted IEDF values, to control a plasma process result.

### Example 14

The method of example 13, where the plasma process result includes at least one of etch rate, etch profile, etch uniformity, deposition rate, and deposition uniformity.

### Example 15

The method of any of examples 1 to 14, where the training the ANN includes Bayesian optimization of ANN hyperparameters.

### Example 16

The method of any of examples 1 to 15, where the one or more operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

### Example 17

The method of any of examples 1 to 16, where the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

### Example 18

A method including: loading a pretrained artificial neural network (ANN) having as inputs one or more operating parameters of a plasma processing system, and as outputs a plurality of ion energy distribution function (IEDF) features corresponding to the one or more operating parameters of the plasma processing system, the pretrained ANN including: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes; receiving one or more runtime operating parameters of the plasma processing system; and predicting at least one IEDF feature utilizing the ANN with the one or more runtime operating parameters used as input.

### Example 19

The method of example 18, where the input layer includes a single input node.

### Example 20

The method of example 18, where the input layer includes five input nodes.

### Example 21

The method of any of examples 18 to 20, where the output layer includes three output nodes.

### Example 22

The method of any of examples 18 to 21, where the single hidden layer is a fully-connected layer.

### Example 23

The method of any of examples 18 to 22, where the single hidden layer includes three hidden nodes.

### Example 24

The method of any of examples 18 to 23, where the single hidden layer includes thirty hidden nodes.

### Example 25

The method of any of examples 18 to 22, where the single hidden layer includes a single hidden node.

### Example 26

The method of any of examples 18 to 25, where the one or more runtime operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

### Example 27

The method of any of examples 18 to 26, where the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

### Example 28

The method of any of examples 18 to 27, further including: setting or altering the one or more runtime operating parameters of the plasma processing system, based on at least one predicted ID feature, to control a plasma process result.

### Example 29

The method of example 28, where the plasma process result includes at least one of etch rate, etch profile, etch uniformity, deposition rate, and deposition uniformity.

### Example 30

A controller including: one or more processors configured to: receive a training data set including: one or more operating parameters of a plasma processing system, where the one or more operating parameters include at least one process setpoint from a process recipe, at least one measured operating parameter, or at least one simulated operating parameter; and a plurality of ion energy distribution function (IEDF) features corresponding to the one or more operating parameters, where the plurality of IEDF features includes at least one measured IEDF feature or at least one simulated IEDF feature; and train an artificial neural network (ANN) using the one or more operating parameters as input, and the plurality of IEDF features as output, where the ANN includes: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes.

### Example 31

The controller of example 30, where the input layer includes a single input node.

### Example 32

The controller of example 30, where the input layer includes five input nodes.

### Example 33

The controller of any of examples 30 to 32, where the output layer includes three output nodes.

### Example 34

The controller of any of examples 30 to 33, where the single hidden layer is a fully-connected layer.

### Example 35

The controller of any of examples 30 to 34, where the single hidden layer includes three hidden nodes.

### Example 36

The controller of any of examples 30 to 35, where the single hidden layer includes thirty hidden nodes.

### Example 37

The controller of any of examples 30 to 34, where the single hidden layer includes a single hidden node.

### Example 38

The controller of example 37, where the one or more processors are further configured to: perform principal component analysis (PCA), utilizing trained weights of the single hidden node, to determine a dependence of the IEDF features on the operating parameters of the plasma processing system.

### Example 39

The controller of any of examples 37 and 38, where the ANN is trained using a rectified linear unit (ReLU) activation function for the single hidden node.

### Example 40

The controller of any of examples 30 to 34, where the single hidden layer includes a plurality of hidden nodes and the ANN is trained using a sigmoid activation function for the plurality of hidden nodes.

### Example 41

The controller of any of examples 30 to 40, where the one or more processors are further configured to: receive runtime operating parameters of the plasma processing system; and predict IEDF values utilizing the ANN with the runtime operating parameters as input.

### Example 42

The controller of example 41, where the one or more processors are further configured to: set or alter the runtime operating parameters of the plasma processing system, based on the predicted IEDF values, to control a plasma process result.

### Example 43

The controller of example 42, where the plasma process result includes at least one of etch rate, etch profile, etch uniformity, deposition rate, and deposition uniformity.

### Example 44

The controller of any of examples 30 to 43, where the training the ANN includes Bayesian optimization of ANN hyperparameters.

### Example 45

The controller of any of examples 30 to 44, where the one or more operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

### Example 46

The controller of any of examples 30 to 45, where the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

### Example 47

A controller including: one or more processors configured to: load a pretrained artificial neural network (ANN) having as inputs one or more operating parameters of a plasma processing system, and as outputs a plurality of ion energy distribution function (IEDF) features corresponding to the one or more operating parameters of the plasma processing system, the pretrained ANN including: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes; receive one or more runtime operating parameters of the plasma processing system; and predict at least one IEDF feature utilizing the ANN with the one or more runtime operating parameters used as input.

### Example 48

The controller of example 47, where the input layer includes a single input node.

### Example 49

The controller of example 47, where the input layer includes five input nodes.

### Example 50

The controller of any of examples 47 to 49, where the output layer includes three output nodes.

### Example 51

The controller of any of examples 47 to 50, where the single hidden layer is a fully-connected layer.

### Example 52

The controller of any of examples 47 to 51, where the single hidden layer includes three hidden nodes.

### Example 53

The controller of any of examples 47 to 52, where the single hidden layer includes thirty hidden nodes.

### Example 54

The controller of any of examples 47 to 51, where the single hidden layer includes a single hidden node.

### Example 55

The controller of any of examples 47 to 54, where the one or more runtime operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

### Example 56

The controller of any of examples 47 to 55, where the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

### Example 57

The controller of any of examples 47 to 56, where the one or more processors are further configured to: set or alter the one or more runtime operating parameters of the plasma processing system, based on at least one predicted ID feature, to control a plasma process result.

### Example 58

The controller of example 57, where the plasma process result includes at least one of etch rate, etch profile, etch uniformity, deposition rate, and deposition uniformity.

### Example 59

A non-transitory computer-readable storage medium storing instructions that, when executed by one or more processors, cause the one or more processors to: receive a training data set including: one or more operating parameters of a plasma processing system, where the one or more operating parameters include at least one process setpoint from a process recipe, at least one measured operating parameter, or at least one simulated operating parameter; and a plurality of ion energy distribution function (IEDF) features corresponding to the one or more operating parameters, where the plurality of IEDF features includes at least one measured IEDF feature or at least one simulated IEDF feature; and train an artificial neural network (ANN) using the one or more operating parameters as input, and the plurality of IEDF features as output, where the ANN includes: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes.

### Example 60

The non-transitory computer-readable storage medium of example 59, where the input layer includes a single input node.

### Example 61

The non-transitory computer-readable storage medium of example 59, where the input layer includes five input nodes.

### Example 62

The non-transitory computer-readable storage medium of any of examples 59 to 61, where the output layer includes three output nodes.

### Example 63

The non-transitory computer-readable storage medium of any of examples 59 to 62, where the single hidden layer is a fully-connected layer.

### Example 64

The non-transitory computer-readable storage medium of any of examples 59 to 63, where the single hidden layer includes three hidden nodes.

### Example 65

The non-transitory computer-readable storage medium of any of examples 59 to 64, where the single hidden layer includes thirty hidden nodes.

### Example 66

The non-transitory computer-readable storage medium of any of examples 59 to 63, where the single hidden layer includes a single hidden node.

### Example 67

The non-transitory computer-readable storage medium of example 66, where the instructions, when executed by the one or more processors, further cause the one or more processors to: perform principal component analysis (PCA), utilizing trained weights of the single hidden node, to determine a dependence of the IEDF features on the operating parameters of the plasma processing system.

### Example 68

The non-transitory computer-readable storage medium of any of examples 66 and 67, where the ANN is trained using a rectified linear unit (ReLU) activation function for the single hidden node.

### Example 69

The non-transitory computer-readable storage medium of any of examples 59 to 63, where the single hidden layer includes a plurality of hidden nodes and the ANN is trained using a sigmoid activation function for the plurality of hidden nodes.

### Example 70

The non-transitory computer-readable storage medium of any of examples 59 to 69, where the instructions, when executed by the one or more processors, further cause the one or more processors to: receive runtime operating parameters of the plasma processing system; and predict IEDF values utilizing the ANN with the runtime operating parameters as input.

### Example 71

The non-transitory computer-readable storage medium of example 70, where the instructions, when executed by the one or more processors, further cause the one or more processors to: set or alter the runtime operating parameters of the plasma processing system, based on the predicted IEDF values, to control a plasma process result.

### Example 72

The non-transitory computer-readable storage medium of example 71, where the plasma process result includes at least one of etch rate, etch profile, etch uniformity, deposition rate, and deposition uniformity.

### Example 73

The non-transitory computer-readable storage medium of any of examples 59 to 72, where the training the ANN includes Bayesian optimization of ANN hyperparameters.

### Example 74

The non-transitory computer-readable storage medium of any of examples 59 to 73, where the one or more operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

### Example 75

The non-transitory computer-readable storage medium of any of examples 59 to 74, where the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

### Example 76

A non-transitory computer-readable storage medium storing instructions that, when executed by one or more processors, cause the one or more processors to: load a pretrained artificial neural network (ANN) having as inputs one or more operating parameters of a plasma processing system, and as outputs a plurality of ion energy distribution function (IEDF) features corresponding to the one or more operating parameters of the plasma processing system, the pretrained ANN including: an input layer including one or more input nodes, where the one or more operating parameters correspond to the one or more input nodes; a single hidden layer including one or more hidden nodes; and an output layer including a plurality of output nodes, where the plurality of IEDF features correspond to the plurality of output nodes; receive one or more runtime operating parameters of the plasma processing system; and predict at least one IEDF feature utilizing the ANN with the one or more runtime operating parameters used as input.

### Example 77

The non-transitory computer-readable storage medium of example 76, where the input layer includes a single input node.

### Example 78

The non-transitory computer-readable storage medium of example 76, where the input layer includes five input nodes.

### Example 79

The non-transitory computer-readable storage medium of any of examples 76 to 78, where the output layer includes three output nodes.

### Example 80

The non-transitory computer-readable storage medium of any of examples 76 to 79, where the single hidden layer is a fully-connected layer.

### Example 81

The non-transitory computer-readable storage medium of any of examples 76 to 80, where the single hidden layer includes three hidden nodes.

### Example 82

The non-transitory computer-readable storage medium of any of examples 76 to 81, where the single hidden layer includes thirty hidden nodes.

### Example 83

The non-transitory computer-readable storage medium of any of examples 76 to 80, where the single hidden layer includes a single hidden node.

### Example 84

The non-transitory computer-readable storage medium of any of examples 76 to 83, where the one or more runtime operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

### Example 85

The non-transitory computer-readable storage medium of any of examples 76 to 84, where the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

### Example 86

The non-transitory computer-readable storage medium of any of examples 76 to 85, where the instructions, when executed by the one or more processors, further cause the one or more processors to: set or alter the one or more runtime operating parameters of the plasma processing system, based on at least one predicted ID feature, to control a plasma process result.

### Example 87

The non-transitory computer-readable storage medium of example 86, where the plasma process result includes at least one of etch rate, etch profile, etch uniformity, deposition rate, and deposition uniformity.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways. “Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method, comprising:
receiving a training data set comprising:
one or more operating parameters of a plasma processing system, wherein the one or more operating parameters include at least one process setpoint from a process recipe, at least one measured operating parameter, or at least one simulated operating parameter; and
a plurality of ion energy distribution function (IEDF) features corresponding to the one or more operating parameters, wherein the plurality of IEDF features includes at least one measured IEDF feature or at least one simulated IEDF feature; and
training an artificial neural network (ANN) using the one or more operating parameters as input, and the plurality of IEDF features as output, wherein the ANN comprises:
an input layer comprising one or more input nodes, wherein the one or more operating parameters correspond to the one or more input nodes;
a single hidden layer comprising one or more hidden nodes; and
an output layer comprising a plurality of output nodes, wherein the plurality of IEDF features correspond to the plurality of output nodes.

2. The method of claim 1, wherein the single hidden layer comprises a single hidden node.

3. The method of claim 2, further comprising:
performing principal component analysis (PCA), utilizing trained weights of the single hidden node, to determine a dependence of the IEDF features on the operating parameters of the plasma processing system.

4. The method of claim 2, wherein the ANN is trained using a rectified linear unit (ReLU) activation function for the single hidden node.

5. The method of claim 1, wherein the single hidden layer comprises a plurality of hidden nodes and the ANN is trained using a sigmoid activation function for the plurality of hidden nodes.

6. The method of claim 1, further comprising:
receiving runtime operating parameters of the plasma processing system; and
predicting IEDF values utilizing the ANN with the runtime operating parameters as input.

7. The method of claim 6, further comprising:
setting or altering the runtime operating parameters of the plasma processing system, based on the predicted IEDF values, to control a plasma process result.

8. The method of claim 7, wherein the plasma process result includes at least one of etch rate, etch profile, etch uniformity, deposition rate, and deposition uniformity.

9. The method of claim 1, wherein the training the ANN comprises Bayesian optimization of ANN hyperparameters.

10. The method of claim 1, wherein the one or more operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

11. The method of claim 1, wherein the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

12. A method, comprising:
loading a pretrained artificial neural network (ANN) having as inputs one or more operating parameters of a plasma processing system, and as outputs a plurality of ion energy distribution function (IEDF) features corresponding to the one or more operating parameters of the plasma processing system, the pretrained ANN comprising:
an input layer comprising one or more input nodes, wherein the one or more operating parameters correspond to the one or more input nodes;
a single hidden layer comprising one or more hidden nodes; and
an output layer comprising a plurality of output nodes, wherein the plurality of IEDF features correspond to the plurality of output nodes;
receiving one or more runtime operating parameters of the plasma processing system; and
predicting at least one IEDF feature utilizing the ANN with the one or more runtime operating parameters used as input.

13. The method of claim 12, wherein the single hidden layer comprises a single hidden node.

14. The method of claim 12, wherein the one or more runtime operating parameters include a source RF power, a substrate RF bias power, a substrate bias potential, a substrate bias pulse time, a substrate bias pulse potential, a bias pulse lag time, a source pulse time, a pulse period, a chamber pressure, or a flow rate of a process gas introduced into the plasma processing system.

15. The method of claim 12, wherein the plurality of IEDF features include at least one of an ion energy and corresponding intensity of an IEDF, a high peak intensity of the IEDF, a low peak intensity of the IEDF, a high peak center ion energy of the IEDF, a maximum ion energy of the IEDF, or a mean ion energy of the IEDF.

16. The method of claim 12, further comprising:
setting or altering the one or more runtime operating parameters of the plasma processing system, based on at least one predicted ID feature, to control a plasma process result.

17. The method of claim 16, wherein the plasma process result includes at least one of etch rate, etch profile, etch uniformity, deposition rate, and deposition uniformity.

18. A controller, comprising:
one or more processors configured to:
receive a training data set comprising:
one or more operating parameters of a plasma processing system, wherein the one or more operating parameters include at least one process setpoint from a process recipe, at least one measured operating parameter, or at least one simulated operating parameter; and
a plurality of ion energy distribution function (IEDF) features corresponding to the one or more operating parameters, wherein the plurality of IEDF features includes at least one measured IEDF feature or at least one simulated IEDF feature; and
train an artificial neural network (ANN) using the one or more operating parameters as input, and the plurality of IEDF features as output, wherein the ANN comprises:
an input layer comprising one or more input nodes, wherein the one or more operating parameters correspond to the one or more input nodes;
a single hidden layer comprising one or more hidden nodes; and
an output layer comprising a plurality of output nodes, wherein the plurality of IEDF features correspond to the plurality of output nodes.

19. The controller of claim 18, wherein the single hidden layer comprises a single hidden node.

20. The controller of claim 19, wherein the one or more processors are further configured to:
perform principal component analysis (PCA), utilizing trained weights of the single hidden node, to determine a dependence of the IEDF features on the operating parameters of the plasma processing system.
